(19) United States
(12) Patent Application Publication
(10) Pub. No.: US 2021/0143044 A1
(43) Pub. Date: May 13, 2021

(54) PLASMA PROCESSING APPARATUS

(71) Applicant: Tokyo Electron Limited, Tokyo (JP)

(72) Inventors: Shinsuke OKA, Miyagi (JP); Kenya IWASAKI, Kumamoto (JP); Hideto SAITO, Miyagi (JP)

(21) Appl. No.: 17/088,123

(22) Filed: Nov. 3, 2020

(30) Foreign Application Priority Data
Nov. 7, 2019 (JP) 2019-202479

(51) Int. Cl. H01L 21/683; H01L 21/67; H01L 21/687

(52) U.S. Cl. CPC H01L 21/6833; H01L 21/68721; H01L 21/67098

(57) ABSTRACT

A plasma processing apparatus includes: a vacuumable processing container; a lower electrode provided inside the processing container and for placing a substrate thereon; an edge ring arranged to surround a periphery of the substrate; an electrostatic chuck provided on the lower electrode to attract the substrate and the edge ring; a heat-transfer-gas supply part for supplying a heat transfer gas between the electrostatic chuck and the edge ring through one or more first through-holes respectively formed in the lower electrode and the electrostatic chuck; and a heat-transfer-gas exhaust part for exhausting the heat transfer gas between the electrostatic chuck and the edge ring through one or more second through-holes respectively formed in the lower electrode and the electrostatic chuck. Electrostatic chuck openings of the second through-holes are formed radially inward of those of the first through-holes between the electrostatic chuck and the edge ring.

### CROSS-REFERENCE TO RELATED APPLICATION

This application is based upon and claims the benefit of priority from Japanese Patent Application No. 2019-202479, filed on Nov. 7, 2019, the entire contents of which are incorporated herein by reference.

### TECHNICAL FIELD

The present disclosure relates to a plasma processing apparatus.

### BACKGROUND

In a semiconductor device manufacturing process, there is a process of performing plasma processing such as etching or film formation on a substrate (hereinafter, also referred to as a wafer) with plasma of a process gas. In such a plasma processing, in order to perform uniform and good processing in a central portion and a peripheral portion of the substrate, an edge ring (focus ring) is arranged to surround the periphery of the substrate on a stage. Further, it is proposed that the control of a temperature of the edge ring by a heat transfer gas is performed independently of the substrate.

### PRIOR ART DOCUMENTS

### Patent Documents

Patent Document 1: Japanese laid-open publication No. 2015-062237

### SUMMARY

According to one embodiment of the present disclosure, there is provided a plasma processing apparatus which includes: a vacuumable processing container; a lower electrode provided inside the processing container and configured to place a substrate thereon; an edge ring arranged so as to surround a periphery of the substrate; an electrostatic chuck provided on an upper surface of the lower electrode to attract the substrate and the edge ring by an electrostatic force; a heat-transfer-gas supply part configured to supply a heat transfer gas between the electrostatic chuck and the edge ring through one or more first through-holes respectively formed in the lower electrode and the electrostatic chuck; and a heat-transfer-gas exhaust part configured to exhaust the heat transfer gas between the electrostatic chuck and the edge ring through one or more second through-holes respectively formed in the lower electrode and the electrostatic chuck, wherein electrostatic chuck openings of the second through-holes are formed radially inward of electrostatic chuck openings of the first through-holes between the electrostatic chuck and the edge ring, and are provided in a bottom surface of a first annular recess formed in a surface of the electrostatic chuck.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a substrate processing apparatus according to an embodiment of the present disclosure.

FIG. 2 is a partial enlarged view illustrating an example of a cross section of a stage according to the present embodiment.

FIG. 3 is a diagram illustrating an example of a surface of a conventional electrostatic chuck.

FIG. 4 is a partial cross-sectional view of an edge ring placement surface taken along line A-A in FIG. 3.

FIG. 5 is a diagram illustrating an example of a surface of an electrostatic chuck according to the present embodiment.

FIG. 6 is a partial cross-sectional view of an edge ring placement surface taken along line B-B in FIG. 5.

FIG. 7 is a diagram illustrating an example of a surface of an electrostatic chuck according to a modification.

FIG. 8 is a partial cross-sectional view of an edge ring placement surface taken along line C-C in FIG. 7.

### DETAILED DESCRIPTION

An embodiment of a plasma processing apparatus will now be described in detail with reference to the drawings. The technology disclosed herein is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the plasma processing apparatus, when the temperature control of an edge ring by a heat transfer gas is performed, leakage of the heat transfer gas into a processing container occurs between an edge ring placement surface of an electrostatic chuck and the edge ring. If the heat transfer gas (e.g., a He gas) leaks, the plasma density near the edge ring changes, which may affect etching characteristics. Therefore, it is expected that the leakage of the heat transfer gas into the processing container is suppressed.

### [Configuration of the Substrate Processing Apparatus 100]

FIG. 1 is a diagram illustrating an example of a substrate processing apparatus according to an embodiment of the present disclosure. The substrate processing apparatus 100 according to the present embodiment is a plasma processing apparatus including parallel flat plate electrodes.

The substrate processing apparatus 100 includes a processing chamber 102 having, for example, a cylindrical processing container made of aluminum whose surface is anodized (alumite-treated). The processing chamber 102 is grounded. A substantially columnar stage 110 configured to place a wafer W thereon is provided at the bottom of the processing chamber 102. The stage 110 includes a plate-shaped insulator 112 made of ceramic or the like, and a susceptor 114 which is provided on the insulator 112 and constitutes a lower electrode.

The stage 110 includes a susceptor temperature controller 117 capable of controlling the susceptor 114 to have a predetermined temperature. The susceptor temperature controller 117 is configured to, for example, circulate a temperature control medium through an annular temperature-control-medium chamber 118 provided inside the susceptor 114 along its circumferential direction.

An electrostatic chuck 120 is provided above the susceptor 114. The electrostatic chuck 120 functions as a substrate holder capable of attracting both the wafer W and an edge ring (focus ring) ER arranged to surround the wafer W. A convex substrate placement portion is formed at an upper center of the electrostatic chuck 120. An upper surface of the substrate placement portion constitutes a substrate placement surface 115 on which the wafer W is placed. An upper surface of a low-height peripheral portion around the substrate placement portion constitutes an edge ring placement surface 116 on which the edge ring ER is placed.

The electrostatic chuck 120 has a configuration in which an electrode 122 is provided inside an insulating material. In the electrostatic chuck 120 according to the present embodiment, the electrode 122 is provided to extend not only to the lower side of the substrate placement surface 115 but also to the lower side of the edge ring placement surface 116 so as to attract both the wafer W and the edge ring ER. In some embodiments, the electrode 122 may be separated so as to attract the wafer W and the edge ring ER separately.

A predetermined DC voltage (e.g., 1.5 kV) is applied to the electrostatic chuck 120 from a DC power supply 123 connected to the electrode 122. Thus, the wafer W and the edge ring ER are electrostatically attracted to the electrostatic chuck 120. Furthermore, the substrate placement portion is formed to have a diameter smaller than that of the wafer W, for example, as illustrated in FIG. 1, and is configured so that an edge portion of the wafer W protrudes outward from the substrate placement portion when the wafer W is placed on the substrate placement portion.

A heat-transfer-gas supply mechanism 200 configured to separately supply a heat transfer gas to a rear surface of the wafer W and a rear surface of the edge ring ER is provided in the stage 110 of the present embodiment. In addition to the He gas, applicable examples of such a heat transfer gas may include an Ar gas, a H₂ gas, an O₂ gas, and a N₂ gas, which can cool down the wafer W and the edge ring ER that receive plasma heat input by efficiently transferring a cooling temperature of the susceptor 114 via the electrostatic chuck 120.

The heat-transfer-gas supply mechanism 200 includes a first heat-transfer-gas supply part 210 configured to supply a first heat transfer gas to the rear surface of the wafer W placed on the substrate placement surface 115, and a second heat-transfer-gas supply part 220 configured to supply a second heat transfer gas to the rear surface of the edge ring ER placed on the edge ring placement surface 116.

Heat conductivity between the susceptor 114 and the wafer W and heat conductivity between the susceptor 114 and the edge ring ER can be separately controlled through the first and second heat transfer gases. For example, pressures and kinds of the first heat transfer gas and the second heat transfer gas may be changed. Thus, although the plasma heat is transferred to the wafer W, it is possible to improve in-plane uniformity of the wafer W and to control in-plane processing characteristics of the wafer W by positively making a temperature difference between the temperature of the wafer W and the temperature of the edge ring ER.

In addition, a heat-transfer-gas exhaust part 180 configured to exhaust the heat transfer gas supplied to the rear surface of the edge ring ER, namely between the electrostatic chuck 120 and the edge ring ER, is provided in the stage 110 of the present embodiment. Specific configurations of the first heat-transfer-gas supply part 210, the second heat-transfer-gas supply part 220, and the heat-transfer-gas exhaust part 180 will be described later.

An upper electrode 130 is provided above the susceptor 114 so as to face the susceptor 114. A space between the upper electrode 130 and the susceptor 114 is defined as a plasma generation space. That is, the plasma generation space is a processing space in which plasma processing is performed. The upper electrode 130 is supported on the upper portion of the processing chamber 102 via an insulating shield member 131.

The upper electrode 130 is mainly configured by an electrode plate 132 and an electrode support 134 detachably supporting the electrode plate 132. The electrode plate 132 is formed of, for example, a silicon member. The electrode support member 134 is formed of, for example, a conductive member such as aluminum whose surface is alumite-treated.

A processing gas supply part 140 configured to introduce a processing gas from a processing gas source 142 into the processing chamber 102 is connected to the electrode support 134. The processing gas source 142 is connected to a gas introduction port 143 of the electrode support 134 via a gas supply pipe 144.

For example, as illustrated in FIG. 1, a mass flow controller (MFC) 146 and an opening/closing valve 148 are provided in the gas supply pipe 144 sequentially from an upstream side. In some embodiments, a flow control system (FCS) may be provided instead of the MFC. A fluorocarbon gas (CₓF_{y}) such as a C₄F₈ gas is supplied from the processing gas source 142 as a processing gas for etching.

The processing gas source 142 supplies, for example, an etching gas for plasma etching. Although only a single processing gas supply system including the gas supply pipe 144, the opening/closing valve 148, the mass flow controller 146, the processing gas source 142, and the like is illustrated in FIG. 1, the substrate processing apparatus 100 includes a plurality of processing gas supply systems. For example, etching gases such as CF₄, O₂, N₂, CHF₃ and the like, flow rates of which are independently controlled, are supplied into the processing chamber 102.

For example, a substantially cylindrical gas diffusion chamber 135 is provided in the electrode support 134 so as to uniformly diffuse the processing gas introduced from the gas supply pipe 144. A plurality of gas discharge holes 136 through which the processing gas is discharged from the gas diffusion chamber 135 into the processing chamber 102, are formed at the bottom of the electrode support 134 and in the electrode plate 132. The processing gas diffused in the gas diffusion chamber 135 can be configured to be uniformly discharged from the plurality of gas discharge holes 136 toward the plasma generation space. In this respect, the upper electrode 130 functions as a shower head for supplying the processing gas.

Furthermore, although not shown, a lifter for lifting up the wafer W with lifter pins is provided in the stage 110 to separate the wafer W from the substrate placement surface 115 of the electrostatic chuck 120.

An exhaust pipe 104 is connected to the bottom portion of the processing chamber 102. An exhaust part 105 is connected to the exhaust pipe 104. The exhaust part 105 includes a vacuum pump such as a turbo molecular pump or the like so as to adjust the interior of the processing chamber 102 in a predetermined depressurized atmosphere. In addition, a loading/unloading port 106 for the wafer W is provided in a sidewall of the processing chamber 102. A gate valve 108 is provided in the loading/unloading port 106. When loading and unloading the wafer W, the gate valve 108 is opened. Then, the wafer W is loaded and unloaded via the loading/unloading port 106 by a transfer arm or the like (not shown).

A power supply device 150 for supplying dual-frequency superimposition power is connected to the susceptor 114 constituting the lower electrode. The power supply device 150 has a first high-frequency power supply mechanism 152 and a second high-frequency power supply mechanism 162. The first high-frequency power supply mechanism 152 supplies a first high-frequency power (high-frequency power for plasma generation) having a first frequency. The second high-frequency power supply mechanism 162 supplies a second high-frequency power (high-frequency power for bias voltage generation) having a second frequency lower than the first frequency.

The first high-frequency power supply mechanism 152 has a first filter 154, a first matcher 156, and a first power supply 158, which are sequentially connected from the side of the susceptor 114. The first filter 154 prevents a power component of the second frequency from entering the side of the first matcher 156. The first matcher 156 performs matching on the first high-frequency power component.

The second high-frequency power supply mechanism 162 has a second filter 164, a second matcher 166, and a second power supply 168, which are sequentially connected from the side of the susceptor 114. The second filter 164 prevents a power component of the first frequency from entering the side of the second matcher 166. The second matcher 166 performs matching on the second high-frequency power component.

A controller (overall control device) 170 is connected to the substrate processing apparatus 100. Respective parts of the substrate processing apparatus 100 are controlled by the controller 170. In addition, an operation part 172 is connected to the controller 170. The operation part 172 has a keyboard for an operator to perform an input operation or the like of commands for managing the substrate processing apparatus 100, a display for visually displaying an operation situation of the substrate processing apparatus 100, or a touch panel having both an input operation terminal function and a situation display function, and the like.

Furthermore, a storage 174 is connected to the controller 170. A program for implementing various processes (plasma processing for the wafer W, and the like) executed by the substrate processing apparatus 100 under the control of the controller 170, processing conditions (recipes) necessary for executing the program, or the like, is stored in the storage 174.

For example, a plurality of processing conditions (recipes) are stored in the storage 174. Each processing condition is a collection of a plurality of parameter values such as control parameters or setting parameters for controlling the respective parts of the substrate processing apparatus 100. Each processing condition has, for example, parameter values such as a flow rate ratio of the processing gas, an internal pressure of the processing chamber, high-frequency power and the like.

In addition, these program and processing conditions may be stored in a hard disk or a semiconductor memory. Furthermore, these program and processing conditions may be set at a predetermined position of the storage 174, while being stored in a portable computer-readable storage medium such as a CD-ROM or a DVD.

The controller 170 reads desired program and processing conditions from the storage 174 based on an instruction from the operation part 172 and controls each part so as to execute a desired process in the substrate processing apparatus 100. In addition, the processing conditions may be edited by the operation of the operation part 172.

In the substrate processing apparatus 100 configured as above, when performing the plasma processing on the wafer W placed on the susceptor 114, the first high-frequency (for example, 100 MHz) of 10 MHz or more is supplied from the first power supply 158 to the susceptor 114 with predetermined power. In addition, the second high-frequency (for example, 3 MHz) of 100 kHz or more and less than 20 MHz is supplied from the second power supply 168 to the susceptor 114 with predetermined power. Thus, plasma of the processing gas is generated between the susceptor 114 and the upper electrode 130 by the action of the first high-frequency, and a self-bias voltage (−Vdc) is generated in the susceptor 114 by the action of the second high-frequency so that the plasma processing can be performed on the wafer W. As described above, it is possible to appropriately control plasma and perform good plasma processing on the wafer W by supplying the first high-frequency and the second high-frequency to the susceptor 114 and superimposing them.

[Details of the Heat-Transfer-Gas Supply Mechanism 200 and the Heat-Transfer-Gas Exhaust Part 180]

Next, the heat-transfer-gas supply mechanism 200 and the heat-transfer-gas exhaust part 180 will be described with reference to FIG. 2. FIG. 2 is a partial enlarged view illustrating an example of a cross section of the stage according to the present embodiment.

As illustrated in FIG. 2, the heat-transfer-gas supply mechanism 200 includes a first heat-transfer-gas supply part 210 and a second heat-transfer-gas supply part 220, which are provided in independent and separate systems. The first heat-transfer-gas supply part 210 is configured to supply the first heat transfer gas at a predetermined pressure between the substrate placement surface 115 of the electrostatic chuck 120 and the rear surface of the wafer W via a first gas flow path 212. Specifically, the first gas flow path 212, which penetrates the insulator 112 and the susceptor 114, communicates with a plurality of gas holes 218 provided in the substrate placement surface 115. The gas holes 218 used herein are formed in substantially the entire surface of the substrate placement surface 115 from the center portion (center portion) to the edge portion (peripheral portion) of the substrate placement surface 115.

A first heat-transfer-gas source 214 for supplying the first heat transfer gas is connected to the first gas flow path 212 via a pressure control valve (PCV) 216. The pressure control valve (PCV) 216 adjusts a flow rate of the first heat transfer gas so that the pressure of the first heat transfer gas becomes a predetermined pressure. Furthermore, the number of first gas flow paths 212 for supplying the first heat transfer gas from the first heat-transfer-gas source 214 therethrough may be one or more.

The second heat-transfer-gas supply part 220 is configured to supply the second heat transfer gas at a predetermined pressure via a second gas flow path 222 between the edge ring placement surface 116 of the electrostatic chuck 120 and the rear surface of the edge ring ER. Specifically, the second gas flow path 222, which penetrates the insulator 112 and the susceptor 114, communicate with a first through-hole 191 that is provided on a bottom surface of an annular recess 190 formed on the edge ring placement surface 116. One or more of first through-holes 191 may be provided. For example, six first through-holes 191 may be formed at equal intervals in the circumferential direction.

A second heat-transfer-gas source 224 for supplying the second heat transfer gas is connected to the second gas flow path 222 via a pressure control valve (PCV) 226. The pressure control valve 226 adjusts a flow rate of the second heat transfer gas so that the pressure of the second heat transfer gas becomes a predetermined pressure. Furthermore, the number of second gas flow paths 222 for supplying the second heat transfer gas from the second heat-transfer-gas source 224 therethrough may be one or more. In addition, the second gas flow paths 222 and the first through-holes 191 may be connected in a one-to-one relationship with each other. Alternatively, a single second gas flow path 222 may be branched into plural flow paths, and may be connected to the plurality of first through-holes 191, respectively.

The heat-transfer-gas exhaust part 180 includes a vacuum pump such as a turbo molecular pump or the like, and exhausts the heat transfer gas supplied between the edge ring placement surface 116 of the electrostatic chuck 120 and the rear surface of the edge ring ER via a third gas flow path 181. Specifically, the third gas flow path 181, which penetrates the insulator 112 and the susceptor 114, communicates with a second through-hole 195 provided on a bottom surface of an annular recess 194 formed on the edge ring placement surface 116. One of more of second through-holes 195 may be provided. For example, six second through-holes 195 may be formed at equal intervals in the circumferential direction. Furthermore, the first through-hole 191 and the second through-hole 195 may be arranged at different positions in the circumferential direction. By doing so, it becomes easier to secure the temperature-control-medium chamber 118, namely a flow path of coolant. Furthermore, it is preferable that the number of the first through-holes 191 and the number of the second through-holes 195 be small from the viewpoint of suppressing unevenness of temperature on the edge ring placement surface 116.

The heat-transfer-gas exhaust part 180 is connected to the third gas flow path 181. The annular recess 194 is exhausted so that an internal pressure of the annular recess 194 when the edge ring ER are placed above the annular recess 194, is maintained at, for example, a pressure equivalent to that of the annular recess 190. One or more of third gas flow paths 181 may be provided. Furthermore, the third gas flow paths 181 and the second through-holes 195 may be connected in a one-to-one relationship with each other. Alternatively, a single third gas flow path 181 may be branched into plural flow paths and may be connected to the plurality of second through-holes 195, respectively.

[Details of the Electrostatic Chuck 120]

Next, details of the electrostatic chuck 120 will be described. First, a conventional electrostatic chuck 320 in which the heat-transfer-gas exhaust part 180 and the third gas flow path 181 are not provided will be described.

FIG. 3 is a diagram illustrating an example of a surface of the conventional electrostatic chuck. FIG. 4 is a partial cross-sectional view of an edge ring placement surface taken along line A-A in FIG. 3. As illustrated in FIGS. 3 and 4, an electrostatic chuck 320 has a substrate placement surface 315 provided in the central portion thereof and edge ring placement surfaces 316 provided in the peripheral portion thereof. An annular recess 392 for preventing the edge ring ER from floating is provided between the substrate placement surface 315 and the edge ring placement surface 316. The substrate placement surface 315 has a region 393 in which an orienter flat (notch) for determining a position of the wafer W is provided. An annular recess 390 is provided between the edge ring placement surfaces 316 in the radial direction. Through-holes 391 are opened in the bottom surface of the annular recess 390. That is, electrostatic chuck openings of the through-holes 391 are provided on the bottom surface of the annular recess 390. The through-holes 391 are connected to a heat-transfer-gas supply part via a gas flow path (not shown). Furthermore, surfaces of the edge ring placement surfaces 316 in contact with the edge ring ER are seal bands.

In the electrostatic chuck 320, when a heat transfer gas is supplied to the annular recess 390 through the through-holes 391, as indicated by an arrow 330, the heat transfer gas leaks into the annular recess 392 and the processing space from a gap between the edge ring placement surfaces 316 and the edge ring ER, as indicated by arrows 331 and 332. For example, since there is a gap between the lateral surface of the substrate placement surface 315 and the edge ring ER, the leaked heat transfer gas is directed upwardly, which causes a reduction in the plasma density near the end portion of the wafer W.

Next, the electrostatic chuck 120 according to the present embodiment will be described. FIG. 5 is a diagram illustrating an example of a surface of the electrostatic chuck according to the present embodiment. FIG. 6 is a partial cross-sectional view of an edge ring placement surface taken along line B-B in FIG. 5.

As illustrated in FIGS. 5 and 6, the electrostatic chuck 120 has the substrate placement surface 115 provided in the central portion thereof and edge ring placement surfaces 116 provided in the peripheral portion thereof. An annular recess 192 for preventing the edge ring ER from floating is provided between the substrate placement surface 115 and the edge ring placement surface 116. The substrate placement surface 115 has a region 193 in which an orienter flat (notch) for determining a position of the wafer W is provided. An annular recess 190 is provided between the edge ring placement surfaces 116 in the radial direction. First through-holes 191 are opened on the bottom surface of the annular recess 190. That is, electrostatic chuck openings of the first through-holes 191 are provided on the bottom surface of the annular recess 190. An annular recess 194 is provided between the edge ring placement surfaces 116 positioned radially inward of the annular recess 190, among the edge ring placement surfaces 116. Second through-holes 195 are opened on the bottom surface of the annular recess 194. That is, electrostatic chuck openings of the second through-holes 195 are provided on the bottom surface of the annular recess 194.

In the example of FIG. 5, six first through-holes 191 and six second through-holes 195 are respectively arranged at equal intervals in the circumferential direction and in an alternate manner. The width of the annular recess 194 is smaller than that of the annular recess 190. Furthermore, the depth of the annular recess 194 from the edge ring placement surface 116 is equal to that of the annular recess 190 from the edge ring placement surface 116. The first through-holes 191 are connected to the second heat-transfer-gas supply part 220 via the second gas flow paths 222. The second through-holes 195 are connected to the heat-transfer-gas exhaust part 180 via the third gas flow paths 181. Furthermore, surfaces of the edge ring placement surfaces 116 in contact with the edge ring ER are seal bands and are subjected to mirror-like finishing.

In the electrostatic chuck 120, a heat transfer gas is supplied to the annular recess 190 through the first through-holes 191, as indicated by an arrow 230. At this time, as indicated by an arrow 231, the heat transfer gas, which tends to leak radially outward between the edge ring placement surface 116 positioned radially outward of the annular recess 190 and the edge ring ER, leaks into the processing space. On the other hand, in the electrostatic chuck 120, as indicated by an arrow 232, the heat transfer gas, which tends to leak radially inward between the edge ring placement surface 116 positioned radially inward of the annular recess 190 and the edge ring ER, reaches the annular recess 194. Since the annular recess 194 is exhausted via the third gas flow paths 181 connected to the second through-holes 195, the heat transfer gas reaching the annular recess 194 is exhausted through the second through-holes 195, as indicated by an arrow 233. That is, it is possible to prevent the heat transfer gas from leaking into the side of the annular recess 192, namely the side of the substrate placement surface 115. At this time, conductance between the edge ring placement surface 116 and the edge ring ER with respect to the second through-holes 195, rather than with respect to the annular recess 192, may be set to a relatively sufficiently large value. For example, the value may be set to 1:99 to 1:1,000. Thus, the leak amount can be 1 sccm or less. Furthermore, it is possible to suppress a reduction in plasma density near the wafer W.

### [Modification]

Next, an electrostatic chuck 120a according to a modification will be described. FIG. 7 is a diagram illustrating an example of a surface of an electrostatic chuck according to a modification. FIG. 8 is a partial cross-sectional view of an edge ring placement surface taken along line C-C in FIG. 7. Like components as those of the aforementioned embodiment will be denoted by like reference numerals and descriptions of the overlapping components and operations that overlap with the aforementioned embodiment will be omitted.

The electrostatic chuck 120a according to the modification further has an annular recess provided radially outward in the radial direction, compared with the electrostatic chuck 120. As illustrated in FIGS. 7 and 8, an annular recess 190 is provided between edge ring placement surfaces 116 of the electrostatic chuck 120a in the radial direction. First through-holes 191 are opened on the bottom surface of the annular recess 190. That is, electrostatic chuck openings of the first through-holes 191 are provided on the bottom surface of the annular recess 190. In addition, an annular recess 194 is provided between the edge ring placement surfaces 116 positioned radially inward of the annular recess 190, among the edge ring placement surfaces 116. Second through-holes 195 are opened on the bottom surface of the annular recess 194. That is, electrostatic chuck openings of the second through-holes 195 are provided on the bottom surface of the annular recess 194. Furthermore, an annular recess 196 is provided between the edge ring placement surfaces 116 positioned radially outward of the annular recess 190, among the edge ring placement surfaces 116. Third through-holes 197 are opened on the bottom surface of the annular recess 196. That is, electrostatic chuck openings of the third through-holes 197 are provided on the bottom surface of the annular recess 196.

In the example of FIG. 7, six first through-holes 191, six second through-holes 195, and six third through-holes 197 are respectively arranged at equal intervals in the circumferential direction and in an alternate manner That is, when the first through-hole 191 is arranged at a certain position in the circumferential direction, the second through-hole 195 and the third through-hole 197 are arranged at positions shifted from the respective position by predetermined distances in the circumferential direction. The widths of the annular recesses 194 and 196 are smaller than that of the annular recess 190. Furthermore, the depths of the annular recesses 194 and 196 from the edge ring placement surface 116 are equal to that of the annular recess 190 from the edge ring placement surface 116. The first through-holes 191 are connected to the second heat-transfer-gas supply part 220 via the second gas flow paths 222. The second through-holes 195 and the third through-holes 197 are connected to the heat-transfer-gas exhaust part 180 via the third gas flow paths 181. Surfaces of the edge ring placement surfaces 116 in contact with the edge ring ER are seal bands and are subjected to mirror-like finishing.

In the electrostatic chuck 120a, the heat transfer gas is supplied to the annular recess 190 through the first through-holes 191, as indicated by an arrow 240. At this time, the heat transfer gas, which tends to leak radially inward from a gap between the edge ring placement surface 116 positioned radially inward of the annular recess 190 and the edge ring ER, reaches the annular recess 194, as indicated by an arrow 241. Since the annular recess 194 is exhausted via through the third gas flow paths 181 connected to the second through-holes 195, the heat transfer gas reaching the annular recess 194 is exhausted through the through-holes 195, as indicated by an arrow 242.

On the other hand, in the electrostatic chuck 120a, the heat transfer gas, which tends to leak radially outward from a gap between the edge ring placement surface 116 positioned radially outward of the annular recess 190 and the edge ring ER, reaches the annular recess 196, as indicated by an arrow 243. Since the annular recess 196 is exhausted via the third gas flow paths 181 connected to the third through-holes 197, the heat transfer gas reaching the annular recess 196 is exhausted through the third through-holes 197, as indicated by an arrow 244. That is, it is possible to prevent the heat transfer gas from leaking to the side of the annular recess 192, namely to the side of the substrate placement surface 115 and the end portion side of the electrostatic chuck 120a. At this time, conductance between the edge ring placement surface 116 and the edge ring ER with respect to the annular recess 192, and conductance between the edge ring placement surface 116 and the edge ring ER with respect to the end portion of the electrostatic chuck 120a, rather than with respect to the second through-holes 195 and the third through-holes 197, may be set to a relatively sufficiently large value. For example, the value may be set to 1:99 to 1:1,000. Thus, it is possible to further suppress a reduction in plasma density near the wafer W. Furthermore, it is possible to suppress deposits from being deposited near the lateral surface of the end portion of the electrostatic chuck 120a and the lower surface of the edge ring ER.

Furthermore, in the aforementioned embodiment, the heat transfer gas, which leaks between the edge ring placement surface 116 and the edge ring ER in the annular recess 194, and between the edge ring placement surface 116 and the edge ring ER in the annular recess 196, from the annular recess 190, is exhausted from the annular recesses 194 and 196. However, the present disclosure is not limited thereto. For example, grooves may be formed in the edge ring placement surfaces 116 between the annular recess 190 and the annular recesses 194 and 196. In this case, conductances through the grooves may be set to such a value that internal pressures of the annular recesses 194 and 196 can be maintained at, for example, pressures equal to that of the annular recess 190.

As described above, according to the present embodiment, the substrate processing apparatus 100 includes the processing container (processing chamber 102), the lower electrode (susceptor 114), the edge ring ER, the electrostatic chuck 120, the heat-transfer-gas supply part (second heat-transfer-gas supply part 220), and the heat-transfer-gas exhaust part 180. The processing container is a vacuumable processing container. Inside the processing container, the lower electrode places the substrate (wafer W) thereon. The edge ring ER is arranged so as to surround the periphery of the substrate. The electrostatic chuck 120 is provided on the upper surface of the lower electrode in order to attract the substrate and the edge ring ER by virtue of electrostatic force. The heat-transfer-gas supply part supplies the heat transfer gas between the electrostatic chuck 120 and the edge ring ER through one or more first through-holes 191 respectively formed in the lower electrode and the electrostatic chuck 120. The heat-transfer-gas exhaust part 180 exhausts the heat transfer gas between the electrostatic chuck 120 and the edge ring ER through one or more second through-holes 195 respectively formed in the lower electrode and the electrostatic chuck 120. Furthermore, the electrostatic chuck openings of the second through-holes 195 are formed radially inward of the electrostatic chuck openings of the first through-holes 191 between the electrostatic chuck 120 and the edge ring ER, and are provided in the bottom surface of a first annular recess (annular recess 194) formed in the surface of the electrostatic chuck 120. As a result, it is possible to suppress the leakage of the heat transfer gas into the processing container.

Furthermore, according to the present embodiment, the electrostatic chuck openings of the first through-holes 191 are provided in the bottom surface of a second annular recess (annular recess 190) formed in the surface of the electrostatic chuck. As a result, the heat transfer gas can be supplied between the electrostatic chuck 120 and the edge ring ER.

In addition, according to the present embodiment, the width of the first annular recess is smaller than the width of the second annular recess. As a result, it is possible to suppress the leakage of the heat transfer gas into the processing container while maintaining the attractive force of the electrostatic chuck 120.

Moreover, according to the present embodiment, the depth of the first annular recess is equal to the depth of the second annular recess. As a result, it is possible to stabilize the internal pressure of the first annular recess at a predetermined pressure.

Furthermore, according to the present embodiment, the electrostatic chuck openings of the first through-holes and the electrostatic chuck openings of the second through-holes may be arranged at different positions in the circumferential direction. As a result, it becomes easier to secure the temperature-control-medium chamber 118, i.e., the flow path of the coolant.

Furthermore, according to the present embodiment, the electrostatic chuck openings of the first through-holes and the electrostatic chuck openings of the second through-holes may be arranged at equal intervals in the circumferential direction and in an alternate manner. As a result, it becomes easier to secure the temperature-control-medium chamber 118, i.e., the flow path of the coolant.

Furthermore, according to the present embodiment, the placement surface of the edge ring ER on the electrostatic chuck 120 is subjected to the mirror-like finishing. As a result, it is possible to reduce the leak amount of the heat transfer gas.

Furthermore, according to the modification, the heat-transfer-gas exhaust part 180 exhausts the heat transfer gas between the electrostatic chuck 120 and the edge ring ER through one or more third through-holes respectively formed in the lower electrode and the electrostatic chuck 120. In addition, the electrostatic chuck openings of the third through-holes 197 are formed radially outward of the electrostatic chuck openings of the first through-holes 191 and are provided in the bottom surface of a third annular recess (annular recess 196) formed in the surface of the electrostatic chuck. As a result, it is possible to further suppress the leakage of the heat transfer gas into the processing container.

It should be noted that the embodiments and modifications disclosed herein are exemplary in all respects and are not restrictive. The above-described embodiments may be omitted, replaced or modified in various forms without departing from the scope and spirit of the appended claims.

According to the present disclosure in some embodiments, it is possible to suppress leakage of a heat transfer gas into a processing container.

What is claimed is:

1. A plasma processing apparatus, comprising:
a vacuumable processing container;
a lower electrode provided inside the processing container and configured to place a substrate thereon;
an edge ring arranged so as to surround a periphery of the substrate;
an electrostatic chuck provided on an upper surface of the lower electrode to attract the substrate and the edge ring by an electrostatic force;
a heat-transfer-gas supply part configured to supply a heat transfer gas between the electrostatic chuck and the edge ring through one or more first through-holes respectively formed in the lower electrode and the electrostatic chuck; and
a heat-transfer-gas exhaust part configured to exhaust the heat transfer gas between the electrostatic chuck and the edge ring through one or more second through-holes respectively formed in the lower electrode and the electrostatic chuck,
wherein electrostatic chuck openings of the second through-holes are formed radially inward of electrostatic chuck openings of the first through-holes between the electrostatic chuck and the edge ring, and are provided in a bottom surface of a first annular recess formed in a surface of the electrostatic chuck.

2. The plasma processing apparatus of claim 1, wherein the electrostatic chuck openings of the first through-holes are provided in a bottom surface of a second annular recess formed in the surface of the electrostatic chuck.

3. The plasma processing apparatus of claim 2, wherein a width of the first annular recess is smaller than a width of the second annular recess.

4. The plasma processing apparatus of claim 3, wherein a depth of the first annular recess is equal to a depth of the second annular recess.

5. The plasma processing apparatus of claim 4, wherein the electrostatic chuck openings of the first through-holes and the electrostatic chuck openings of the second through-holes are arranged at different positions in a circumferential direction.

6. The plasma processing apparatus of claim 5, wherein the electrostatic chuck openings of the first through-holes and the electrostatic chuck openings of the second through-holes are arranged at equal intervals in the circumferential direction and in an alternate manner.

7. The plasma processing apparatus of claim 6, wherein a placement surface of the edge ring in the electrostatic chuck is subjected to a mirror-like finishing.

8. The plasma processing apparatus of claim 7, wherein the heat-transfer-gas exhaust part is further configured to exhaust the heat transfer gas between the electrostatic chuck and the edge ring through one or more third through-holes respectively formed in the lower electrode and the electrostatic chuck, and
wherein electrostatic chuck openings of the third through-holes are formed radially outward of the electrostatic chuck openings of the first through-holes between the electrostatic chuck and the edge ring, and are provided in a bottom surface of a third annular recess formed in the surface of the electrostatic chuck.

9. The plasma processing apparatus of claim 1, wherein the electrostatic chuck openings of the first through-holes and the electrostatic chuck openings of the second through-holes are arranged at different positions in a circumferential direction.

10. The plasma processing apparatus of claim 1, wherein a placement surface of the edge ring in the electrostatic chuck is subjected to a mirror-like finishing.

11. The plasma processing apparatus of claim 1, wherein the heat-transfer-gas exhaust part is further configured to exhaust the heat transfer gas between the electrostatic chuck and the edge ring through one or more third through-holes respectively formed in the lower electrode and the electrostatic chuck, and
wherein electrostatic chuck openings of the third through-holes are formed radially outward of the electrostatic chuck openings of the first through-holes between the electrostatic chuck and the edge ring, and are provided in a bottom surface of a third annular recess formed in the surface of the electrostatic chuck.
